(19) United States
(12) Patent Application Publication
(10) Pub. No.: US 2007/0252260 A1
(43) Pub. Date: Nov. 1, 2007

(54) Stacked die packages

(75) Inventors: Tay Liang Chee, Singapore (SG); Tan Kok Chua, Singapore (SG); Leow See Hiong, Singapore (SG)

Correspondence Address: WELLS ST. JOHN P.S., 601 W. FIRST AVENUE, SUITE 1300, SPOKANE, WA, 99201, US

(73) Assignee: Micron Technology, Inc.

(21) Appl. No.: 11/413,439

(22) Filed: Apr. 28, 2006

(51) Int. Cl. H01L 23/02

(52) U.S. Cl. 257/686

(57) ABSTRACT

The invention includes stacked die packages. In one implementation, a stacked die package includes a base substrate and at least two pairs of flip chip stacks. Each pair comprises a flip chip in die up orientation, a flip chip in die down orientation and an interposer substrate to which the die up and die down flip chips electrically connect. A first of the at least two pairs of flip chip stacks is adhesively bonded to the base substrate. A second of the at least two pairs of flip chip stacks is adhesively bonded to the first pair of flip chip stacks by an insulative adhesive. Electrically conductive interconnects electrically connect the interposer substrates of at least the first and second stacks with the base substrate. Other aspects and implementations are contemplated.

### TECHNICAL FIELD

This invention relates to stacked die packages.

### BACKGROUND OF THE INVENTION

A plurality of integrated circuits is typically fabricated relative to a single substrate or wafer. The circuits are thereafter cut into individual pieces commonly referred to as die or chips. Such are physically mounted and electrically connected with other substrates. In many instances, the chips are encapsulated into and by an insulative and protective material. Also, such packages might include multiple chips stacked atop one another. A continuing goal in integrated circuitry fabrication and packaging is to minimize the volume occupied by the circuit including the stack height of packages containing multiple chips.

While the invention was motivated in addressing the above identified issues, it is in no way so limited. The invention is only limited by the accompanying claims as literally worded, without interpretative or other limiting reference to the specification, and in accordance with the doctrine of equivalents.

### SUMMARY

The invention includes stacked die packages. In one implementation, a stacked die package includes a base substrate and at least two pairs of flip chip stacks. Each pair comprises a flip chip in die up orientation, a flip chip in die down orientation and an interposer substrate to which the die up and die down flip chips electrically connect. A first of the at least two pairs of flip chip stacks is adhesively bonded to the base substrate. A second of the at least two pairs of flip chip stacks is adhesively bonded to the first pair of flip chip stacks by an insulative adhesive. Electrically conductive interconnects electrically connect the interposer substrates of at least the first and second stacks with the base substrate.

In one implementation, a stacked die package includes a base substrate having an upper surface and a lower surface and at least two pairs of flip chip stacks. Each pair comprises a flip chip in die up orientation, a flip chip in die down orientation and an interposer substrate to which the die up and die down flip chips electrically connect. A first of the at least two pairs of flip chip stacks is adhesively bonded to the base substrate. The die up flip chip of the first pair has a bottom surface that is adhesively bonded to the upper surface of the base substrate by at least one of a) a homogenous adhesive composition contacting the die up flip chip bottom surface of the first pair and contacting the base substrate upper surface, and b) a tape comprising an insulative substrate having an upper adhesive contacting the die up flip chip bottom surface of the first pair and a lower adhesive contacting the base substrate upper surface. A second of the at least two pairs of flip chip stacks id adhesively bonded to the first pair of flip chip stacks. Electrically conductive interconnects electrically connect the interposer substrates of at least the first and second stacks with the base substrate.

In one implementation, a stacked die package includes a base substrate and at least two pairs of flip chip stacks. Each pair comprises a flip chip in die up orientation, a flip chip in die down orientation and an interposer substrate to which the die up and die down flip chips electrically connect. A first of the at least two pairs of flip chip stacks is adhesively bonded to the base substrate. A second of the at least two pairs of flip chip stacks is adhesively bonded to the first pair of flip chip stacks. The die up flip chip of the second pair has a bottom surface. The die down flip chip of the first pair has an upper surface. The die up flip chip bottom surface of the second pair is adhesively bonded to the die up flip chip upper surface of the first pair. Electrically conductive interconnects electrically connect the interposer substrates of at least the first and second stacks with the base substrate.

In one implementation, a stacked die package includes a base substrate and at least two pairs of flip chip stacks. Each pair comprises a flip chip in die up orientation, a flip chip in die down orientation and an interposer substrate to which the die up and die down flip chips electrically connect. A first of the at least two pairs of flip chip stacks is adhesively bonded to the base substrate. A second of the at least two pairs of flip chip stacks is adhesively bonded to the first pair of flip chip stacks. Electrically conductive interconnects electrically connect the interposer substrates of at least the first and second stacks with the base substrate. At least one of the interposer substrates of the first and second stacks has an upper surface conductive contact which is electrically connected to the base substrate by a wire.

In one implementation, a stacked die package includes a base substrate and at least two pairs of flip chip stacks. Each pair comprises a flip chip in die up orientation, a flip chip in die down orientation and an interposer substrate to which the die up and die down flip chips electrically connect. A first of the at least two pairs of flip chip stacks is adhesively bonded to the base substrate. A second of the at least two pairs of flip chip stacks is adhesively bonded to the first pair of flip chip stacks. A first electrically conductive interconnect extends directly from and electrically interconnects the interposer of the first stack directly to the base substrate. A second electrically conductive interconnect extends directly from and electrically interconnects the interposer substrate of the second stack directly to the base substrate.

In one implementation, a stacked die package includes a base substrate and at least two pairs of flip chip stacks. Each pair comprises a flip chip in die up orientation, a flip chip in die down orientation and an interposer substrate to which the die up and die down flip chips electrically connect. A first of the at least two pairs of flip chip stacks is adhesively bonded to the base substrate. A second of the at least two pairs of flip chip stacks is adhesively bonded to the first pair of flip chip stacks. Electrically conductive interconnects electrically connect the interposer substrates of at least the first and second stacks with the base substrate. An electrically insulative encapsulant is received over the second stack, between the interposer substrates of the first and second stacks, and between the interposer substrate of the first stack and the base substrate.

Other aspects and implementations are contemplated.

### BRIEF DESCRIPTION OF THE DRAWINGS

Preferred embodiments of the invention are described below with reference to the following accompanying drawings.

FIG. 1 is a diagrammatic sectional view of a stacked die package in accordance with aspects of the invention.

FIG. 2 is an exploded view of FIG. 1 showing only some of the components of FIG. 1.

FIG. 3 is a diagrammatic sectional view of another stacked die package in accordance with aspects of the invention.

FIG. 4 is an exploded view of FIG. 3 showing only some of the components of FIG. 3.

FIG. 5 is a diagrammatic sectional view of still another stacked die package in accordance with aspects of the invention.

### DETAILED DESCRIPTION OF THE PREFERRED EMBODIMENTS

This disclosure of the invention is submitted in furtherance of the constitutional purposes of the U.S. Patent Laws “to promote the progress of science and useful arts” (Article 1, Section 8).

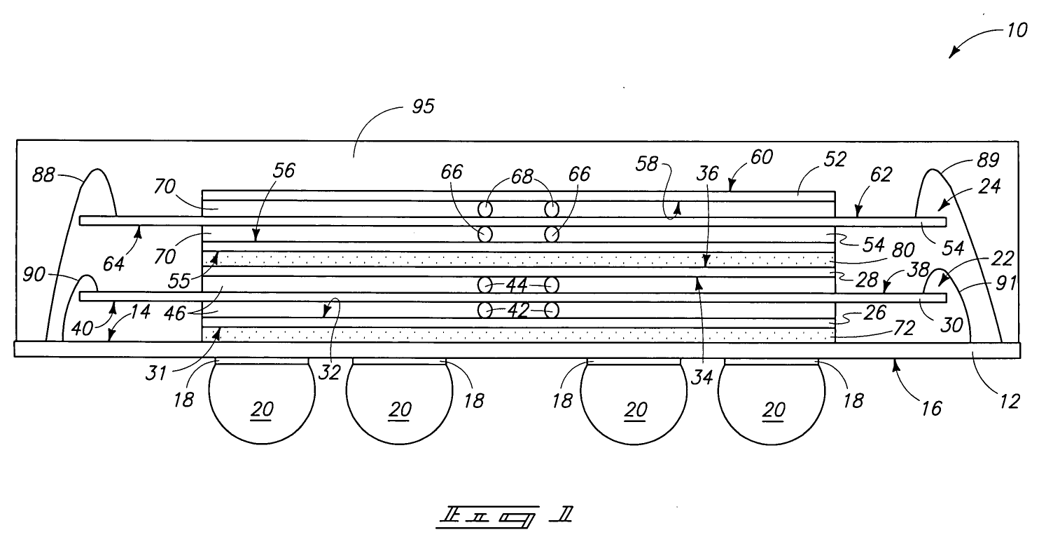

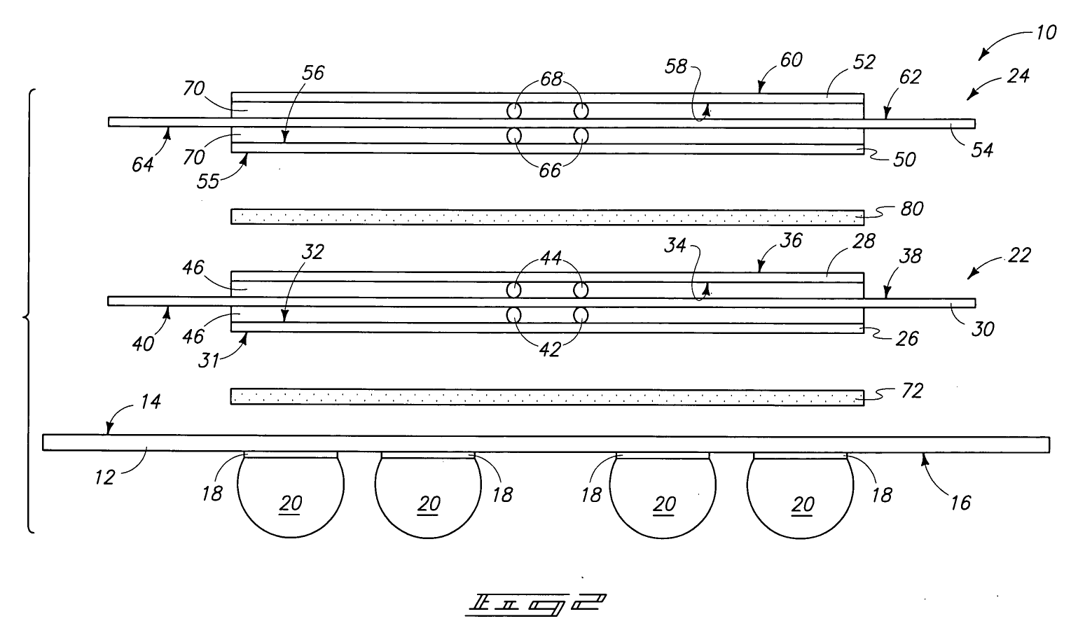

Preferred implementations of stacked die packages in accordance with the invention are described with reference to FIGS. 1-5. Referring initially to FIGS. 1 and 2, a first embodiment stacked die package is indicated generally with reference numeral 10. FIG. 2 is an exploded view of FIG. 1 wherein an encapsulant and certain electrical interconnects in FIG. 1 are not shown for clarity. A stacked die package comprises a base substrate 12 having an upper surface 14 and a lower surface 16. Lower surface 16 is depicted as comprising conductive contact pads or surfaces 18 to which a plurality of conductive balls or bumps 20 have been provided. Typically and preferably, conductive paths/traces (not shown) would extend from surfaces 18 through base substrate 12 to upper surface 14 to conductive pads thereon (not shown) to which electrical connection can be made to the upper or frontside of base substrate 12. Bulk material of substrate 12 is preferably electrically insulative, with conventional printed circuit board material comprising but one example. Base substrate 12 is exemplary only, and any alternate configuration or construction (whether existing or yet-to-be developed) is contemplated.

Stacked die packages in accordance with the invention comprise at least two pairs of flip chip stacks. Each pair comprises a flip chip in die up orientation, a flip chip in die down orientation, and an interposer substrate to which the die up and die down flip chips electrically connect. FIGS. 1 and 2 depict an exemplary first flip chip pair 22 and a second flip chip pair 24. First and second pairs 22 and 24 are shown to be essentially identical in construction, although such is of course not required. The depicted embodiments are also exemplary only. First flip chip pair 22 includes a flip chip 26 in die up orientation, a flip chip 28 in die down orientation, and an interposer substrate 30 to which die up flip chip 26 and die down flip chip 28 electrically connect. Die up flip chip 26 of first pair 22 has a bottom surface 31 and an upper surface 32. Die down flip chip 28 of first pair 22 comprises a bottom surface 34 and an upper surface 36. Interposer substrate 30 is depicted as comprising an upper surface 38 and a lower surface 40.

Die up flip chip 26 is depicted as having been bumped or other provided with conductors 42 which electrically connect with bond or contact pads (not shown) on die up flip chip upper surface 32 and electrically connect with bond or contact pads (not shown) on interposer substrate bottom surface 40. Die down flip chip 28 has also been bumped or otherwise provided with conductors 44 which electrically connect with bond or contact pads (not shown) formed on die down bottom surface 34 and electrically connect with bond or contact pads (not shown) on interposer substrate upper surface 38. More conductors 42 and 44, and associated contact or bond pads, would typically be provided with respect to die up flip chip 26, die down flip chip 28 and interposer substrate 30, with only two each being shown by way of example only.

Interposer substrate 30 would typically comprise a dielectric/insulative material having conductive paths/traces or lines (not shown) formed thereon or therethrough, as is conventional or yet-to-be developed, for redistributing desired conductive interconnects to locations on upper surface 38 and/or lower surface 40 of interposer substrate 30. Exemplary materials include insulative printed circuit board materials. Interposer substrate 30 might alternately, by way of example only, comprise z-axis conductive material, and otherwise be x-axis and y-axis insulative. Exemplary and preferred electrically insulative material 46 is received intermediate die down flip chip 28 and interposer substrate upper surface 38, and between die up flip chip 26 and interposer substrate bottom surface 40.

Second flip chip stack 24 is depicted in the exemplary preferred embodiment as comprising an analogous construction. Specifically, second flip chip pair 24 includes a flip chip 50 in die up orientation, a flip chip 52 in die down orientation, and an interposer substrate 54 to which die up flip chip 50 and die down flip chip 52 electrically connect. Die up flip chip 50 of second pair 24 has a bottom surface 55 and an upper surface 56. Die down flip chip 52 of second pair 24 comprises a bottom surface 58 and an upper surface 60. Interposer substrate 54 is depicted as comprising an upper surface 62 and a lower surface 64.

Die up flip chip 50 is depicted as having been bumped or other provided with conductors 66 which electrically connect with bond or contact pads (not shown) on die up flip chip upper surface 56 and electrically connect with bond or contact pads (not shown) on interposer substrate bottom surface 64. Die down flip chip 52 has also been bumped or otherwise provided with conductors 68 which electrically connect with bond or contact pads (not shown) formed on die down bottom surface 58 and electrically connect with bond or contact pads (not shown) on interposer substrate upper surface 62. More conductors 66 and 68, and associated contact or bond pads, would typically be provided with respect to die up flip chip 50, die down flip chip 52 and interposer substrate 54, with only two each being shown by way of example only.

First flip chip stack pair 22 is adhesively bonded to base substrate 12. In one preferred implementation, a layer of adhesive 72 is received between first flip chip stack pair 22 and base substrate 16. Further in the depicted preferred embodiment, bottom surface 31 of die up flip chip 26 of first pair 22 is adhesively bonded by adhesive 72 to upper surface 14 of base substrate 12. In one preferred implementation, adhesive 72 is electrically insulative. Alternately, such might be semiconductive and/or conductive (less preferred), for example where base substrate 12 comprises an insulative material and no conductive traces or contacts are received on upper surface 14 of base substrate 12 over which first pair 22 overlies.

In one preferred implementation, bottom surface 31 of die up flip chip 26 of first pair 22 is adhesively bonded to upper surface 14 of base substrate 12 by at least one of a) a homogeneous adhesive composition contacting die up flip chip bottom surface 31 of first pair 22 and contacting base substrate upper surface 14, and b) a tape comprising an insulative substrate having an upper adhesive contacting the die up flip chip bottom surface of the first pair, and a lower adhesive contacting the base substrate surface.

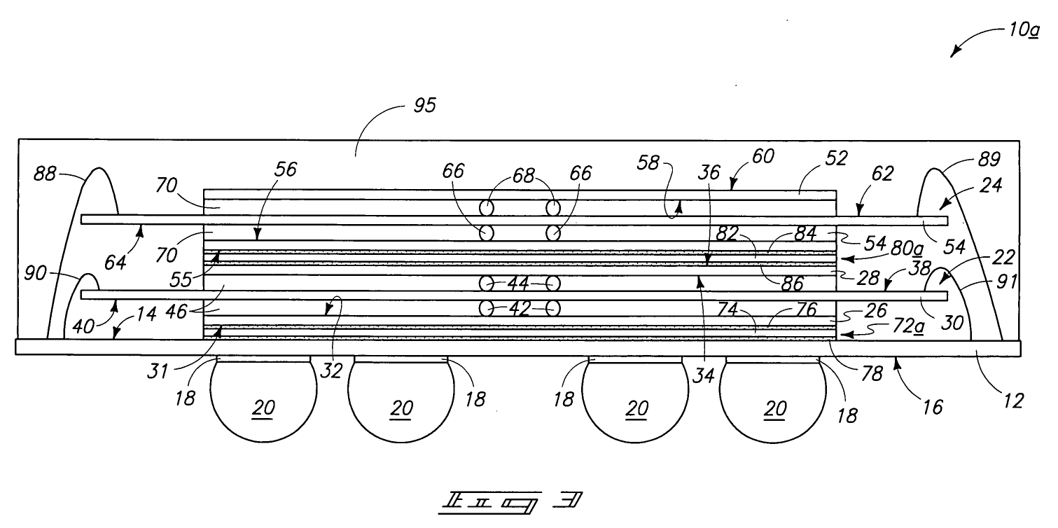

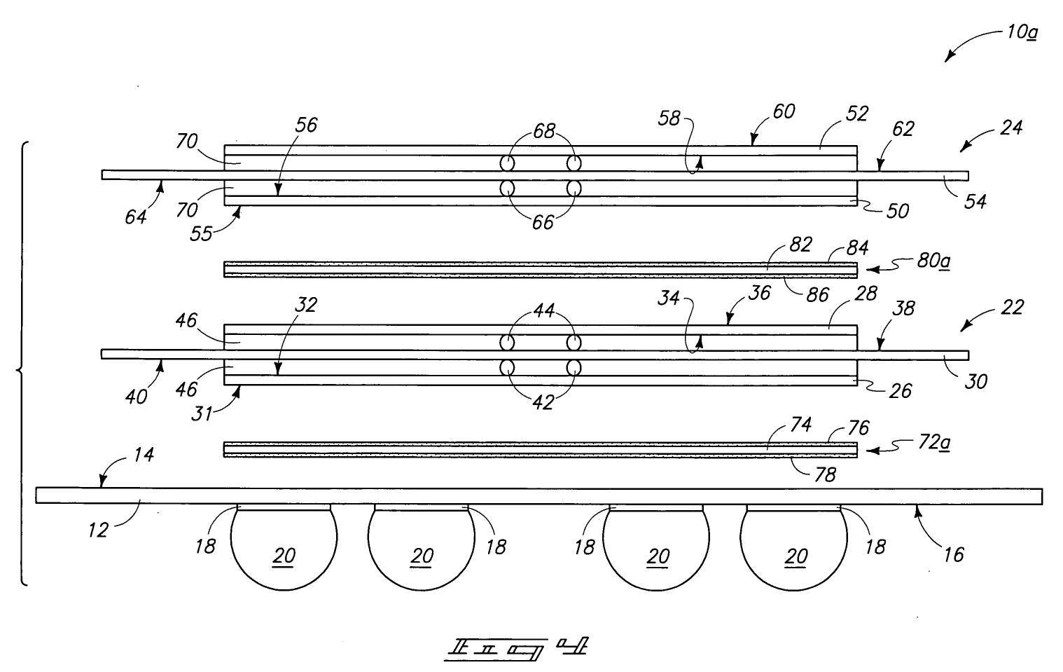

By way of example only, FIGS. 1 and 2 depict an exemplary homogeneous adhesive composition 72. An exemplary alternate embodiment stacked die package 10a is depicted in FIGS. 3 and 4. Like numerals from the first-described embodiment are utilized where appropriate, with differences being indicated with the suffix “a”, or with different numerals. FIGS. 3 and 4 depict an alternate embodiment adhesive 72a in the form of a tape comprising an insulative substrate 74 having an upper adhesive 76 contacting die up flip chip bottom surface 31 of first pair 22, and a lower adhesive 78 contacting base substrate upper surface 14. Adhesive 72a is preferably and typically overall effectively electrically insulative, although in some instances one, more, or all of features 76, 74 and 78 might be semiconductive and/or electrically conductive, and also which is less preferred.

Referring to FIGS. 1 and 2, second flip chip stack pair 24 is adhesively bonded to first flip chip stack pair 22. In the depicted preferred embodiment, such is by an adhesive 80 which is preferably an insulative adhesive. Alternately but less preferred, some or all of adhesive 80 might comprise semiconductive and/or electrically conductive materials. Regardless, in the depicted preferred implementation, bottom surface 55 of die up flip chip 50 of second pair 24 is adhesively bonded to upper surface 36 of die down flip chip 28 of first pair 22 by adhesive 80. In one preferred implementation, adhesive bonding of first pair 22 and second pair 24 with one another is by an adhesive comprising at least one: of a) a homogeneous adhesive composition contacting die up flip chip bottom surface 55 of second pair 24, and contacting die down flip chip upper surface 36 of first pair 22, and b) a tape comprising an insulative substrate having an upper adhesive contacting the die up flip chip bottom surface of the second substrate, and a lower adhesive contacting the die down flip chip upper surface of the first pair.

By way of example only, FIGS. 1 and 2 diagrammatically depict an exemplary homogeneous such adhesive composition. FIGS. 3 and 4 of stacked die package 10a depict an adhesive 80a as constituting a tape comprising an insulative substrate 82 having an upper adhesive 84 contacting die, up flip chip bottom surface 55 of second pair 24, and a lower adhesive 86 contacting die down flip chip upper surface 36 of first pair 22. Alternate adhesives 80/80a are also, of course, contemplated. Also, FIGS. 1 and 2 by way of example only, might be considered as diagrammatically depicting homogeneous adhesive compositions 72 and 80 wherein FIGS. 3 and 4 depict a stacked die package incorporating exemplary tape adhesives 72a and 80a. Of course, any combination of homogeneous and tape adhesives 72/72a/80/80a might be also be utilized.

Electrically conductive interconnects electrically connect the interposer substrates of first pair of flip chip stack 22 and second pair of flip chip stack 24 with base substrate 12. An electrically conductive interconnect, electrically connecting the interposer substrate of the second stack with the base substrate might occur first to the interposer substrate of the first stack, and therefrom to the base substrate. Alternately and more preferred, an electrically conductive interconnect connecting the interposer substrate of the second pair might extend directly from and electrically interconnect the interposer substrate of the second stack to the base substrate. In the context of this document, such a “direct” interconnect means without there being any intervening through-substrate connection.

In one implementation, at least one of the electrically conductive interconnects comprises a wire. In one implementation at least one of the interposer substrates of the first and second stacks has an upper surface conductive contact which is electrically connected to the base substrate by a wire. For example and by way of example only, FIG. 1 depicts preferred exemplary wire interconnects 88 and 89 directly interconnecting interposer substrate 54 of second pair 24 with base substrate 12, and wire interconnects 90 and 91 electrically interconnecting interposer substrate 30 of first pair 22 with base substrate 12. More wire interconnects extending between the respective interposer substrates and base substrate would typically be utilized, with only two for each being shown for simplicity/clarity in the drawings.

Further, by way of example only, stacked die package 10 of FIG. 1 depicts the wire interconnects extending from upper surface conductive contacts (not specifically designated) of their respective interposer substrates to conductive contacts (not specifically designated) of upper surface 14 of base substrate 12. Alternate interconnections are also, of course, contemplated and not necessarily requiring upper surface-to-upper surface interconnections, nor direct interconnections as depicted. For example and by way of example only, alternate exemplary connections might be by wire, conductive ball, or otherwise, from the bottom surfaces of the respective interposer substrates to the base substrate directly, or perhaps such connection with respect to second pair 24 from interposer substrate 54 to interposer substrate 30 and then to base substrate 14. However, most preferred are embodiments as depicted.

Referring to FIG. 1, the exemplary preferred embodiment comprises an electrically insulative encapsulant 95 received over second stack 24, between interposer substrate 54 of second stack 24 and interposer substrate 30 of first stack 22, and between interposer substrate 30 of first stack 22 and base substrate 12. Any suitable or yet-to-be developed encapsulant/passivation/insulating material is, of course, contemplated.

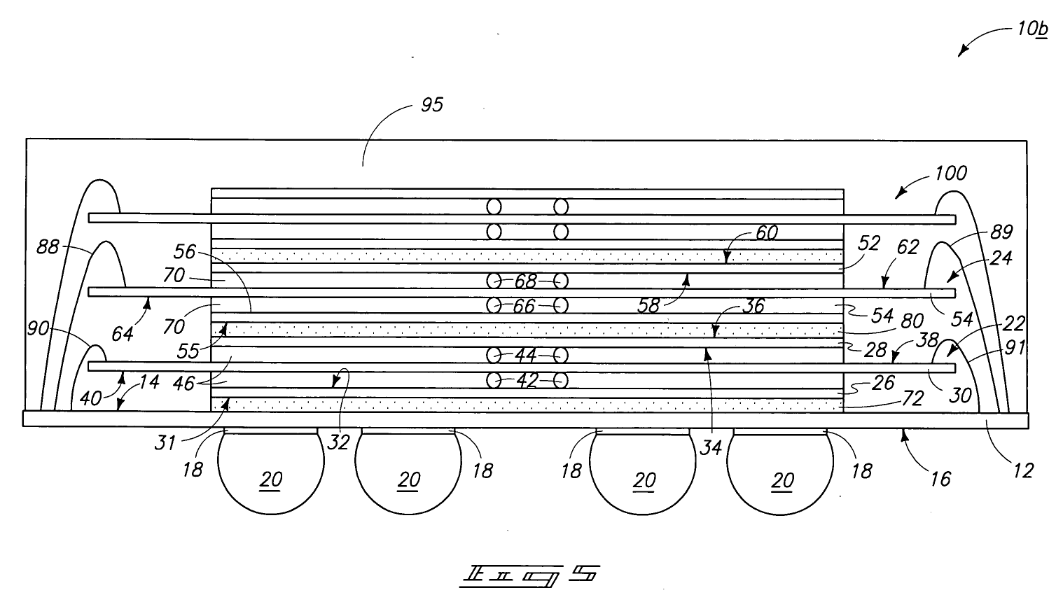

FIGS. 1-4 depict exemplary embodiments where the number of pairs of flip chip stacks is only two. Aspects of the invention also contemplate embodiments wherein the pairs of flip chip stacks number more than two, for example numbering at least three. Such an exemplary embodiment, by way of example only, is shown in connection with a stacked die package 10b in FIG. 5. Like numerals from the first-described embodiment are utilized where appropriate, with differences being indicated with the suffix “b”, or with different numerals. Stacked die package 10b is depicted as comprising a third flip chip stack pair 100 which is adhesively bonded to second flip chip stack pair 24. Exemplary construction and bonding of third pair 100 to second pair 24, and interconnection relative to base substrate 12, might occur through any of the techniques described above regarding electrical and physical interconnection with respect to first pair 22 and 24 and base substrate 12.

A typical preferred method of manufacture in accordance with the depicted preferred implementations would be to initially adhere first flip chip stack pair 22 to base substrate 14, and subsequently conduct desired wire bond interconnects from interposer substrate 30 to base substrate 12. Thereafter, second flip chip stack pair 24 could be adhesively bonded to first flip chip stack pair 22, and subsequent wire bonding conducted from interposer substrate 30 to base substrate 12.

In compliance with the statute, the invention has been described in language more or less specific as to structural and methodical features. It is to be understood, however, that the invention is not limited to the specific features shown and described, since the means herein disclosed comprise preferred forms of putting the invention into effect. The invention is, therefore, claimed in any of its forms or modifications within the proper scope of the appended claims appropriately interpreted in accordance with the doctrine of equivalents.

1. A stacked die package comprising:
a base substrate;
at least two pairs of flip chip stacks, each pair comprising a flip chip in die up orientation, a flip chip in die down orientation and an interposer substrate to which the die up and die down flip chips electrically connect;
a first of the at least two pairs of flip chip stacks adhesively bonded to the base substrate;
a second of the at least two pairs of flip chip stacks adhesively bonded to the first pair of flip chip stacks by an insulative adhesive; and
electrically conductive interconnects electrically connecting the interposer substrates of at least the first and second stacks with the base substrate.

2. The package of claim 1 wherein the die up flip chip of the first pair has a bottom surface that is adhesively bonded to the upper surface of the base substrate by at least one of a) a homogenous adhesive composition contacting the die up flip chip bottom surface of the first pair and contacting the base substrate upper surface, and b) a tape comprising an insulative substrate having an upper adhesive contacting the die up flip chip bottom surface of the first pair and a lower adhesive contacting the base substrate upper surface.

3. The package of claim 1 wherein the die up flip chip of the second pair has a bottom surface, the die down flip chip of the first pair has an upper surface, the die up flip chip bottom surface of the second pair being adhesively bonded to the die up flip chip upper surface of the first pair.

4. The package of claim 1 wherein at least one of the interposer substrates of the first and second stacks has an upper surface conductive contact which is electrically connected to the base substrate by a wire.

5. The package of claim 1 wherein the electrically conductive interconnects comprise:
a first electrically conductive interconnect extending directly from and electrically interconnecting the interposer substrate of the first stack directly to the base substrate; and
a second electrically conductive interconnect extending directly from and electrically interconnecting the interposer substrate of the second stack directly to the base substrate.

6. The package of claim 1 comprising an electrically insulative encapsulant received over the second stack, between the interposer substrates of the first and second stacks, and between the interposer substrate of the first stack and the base substrate.

7. The package of claim 1 wherein the die up flip chip of the second pair comprises a bottom surface and the die down flip chip of the first pair comprises an upper surface, the insulative adhesive comprising at least one of a) a homogenous adhesive composition contacting the die up flip chip bottom surface of the second pair and contacting the die down flip chip upper surface of the first pair, and b) a tape comprising an insulative substrate having an upper adhesive contacting the die up flip chip bottom surface of the second pair and a lower adhesive contacting the die down flip chip upper surface of the first pair.

8. The package of claim 7 wherein said at least one comprises said homogenous adhesive.

9. The package of claim 7 wherein said at least one comprises said tape.

10. The package of claim 1 wherein the pairs of flip chip stacks number only two.

11. The package of claim 1 wherein the pairs of flip chip stacks number at least three, a third of the at least three pairs of flip chip stacks being adhesively bonded to the second pair of flip chip stacks.

12. The package of claim 1 wherein at least one of the electrically conductive interconnects comprises a wire.

13. The package of claim 1 wherein at least one of the electrically conductive interconnects connecting the interposer substrate of the first stack with the base substrate comprises a wire.

14. The package of claim 1 wherein at least one of the electrically conductive interconnects connecting the interposer substrate of the second stack with the base substrate comprises a wire.

15. The package of claim 1 wherein at least one of the electrically conductive interconnects connecting the interposer substrate of the first stack with the base substrate comprises a wire, and wherein at least one of the electrically conductive interconnects connecting the interposer substrate of the second stack with the base substrate comprises a wire.

16. The package of claim 1 wherein the first pair of flip chip stacks is adhesively bonded to the base substrate by a layer of insulative adhesive.

17. A stacked die package comprising:
a base substrate having an upper surface and a lower surface;
at least two pairs of flip chip stacks, each pair comprising a flip chip in die up orientation, a flip chip in die down orientation and an interposer substrate to which the die up and die down flip chips electrically connect;
a first of the at least two pairs of flip chip stacks adhesively bonded to the base substrate, the die up flip chip of the first pair having a bottom surface that is adhesively bonded to the upper surface of the base substrate by at least one of a) a homogenous adhesive composition contacting the die up flip chip bottom surface of the first pair and contacting the base substrate upper surface, and b) a tape comprising an insulative substrate having an upper adhesive contacting the die up flip chip bottom surface of the first pair and a lower adhesive contacting the base substrate upper surface;
a second of the at least two pairs of flip chip stacks adhesively bonded to the first pair of flip chip stacks; and
electrically conductive interconnects electrically connecting the interposer substrates of at least the first and second stacks with the base substrate.

18. The package of claim 17 wherein the die up flip chip of the second pair has a bottom surface, the die down flip chip of the first pair has an upper surface, the die up flip chip bottom surface of the second pair being adhesively bonded to the die up flip chip upper surface of the first pair.

19. The package of claim 17 wherein at least one of the interposer substrates of the first and second stacks has an upper surface conductive contact which is electrically connected to the base substrate by a wire.

20. The package of claim 17 wherein the electrically conductive interconnects comprise:
a first electrically conductive interconnect extending directly from and electrically interconnecting the interposer substrate of the first stack directly to the base substrate; and
a second electrically conductive interconnect extending directly from and electrically interconnecting the interposer substrate of the second stack directly to the base substrate.

21. The package of claim 17 comprising an electrically insulative encapsulant received over the second stack, between the interposer substrates of the first and second stacks, and between the interposer substrate of the first stack and the base substrate.

22. The package of claim 17 wherein said at least one comprises said homogenous adhesive.

23. The package of claim 17 wherein said at least one comprises said tape.

24. A stacked die package comprising:
a base substrate;
at least two pairs of flip chip stacks, each pair comprising a flip chip in die up orientation, a flip chip in die down orientation and an interposer substrate to which the die up and die down flip chips electrically connect;
a first of the at least two pairs of flip chip stacks adhesively bonded to the base substrate;
a second of the at least two pairs of flip chip stacks adhesively bonded to the first pair of flip chip stacks, the die up flip chip of the second pair having a bottom surface, the die down flip chip of the first pair having an upper surface, the die up flip chip bottom surface of the second pair being adhesively bonded to the die up flip chip upper surface of the first pair; and
electrically conductive interconnects electrically connecting the interposer substrates of at least the first and second stacks with the base substrate.

25-32. (canceled)

33. A stacked die package comprising:
a base substrate;
at least two pairs of flip chip stacks, each pair comprising a flip chip in die up orientation, a flip chip in die down orientation and an interposer substrate to which the die up and die down flip chips electrically connect;
a first of the at least two pairs of flip chip stacks adhesively bonded to the base substrate;
a second of the at least two pairs of flip chip stacks adhesively bonded to the first pair of flip chip stacks; and
electrically conductive interconnects electrically connecting the interposer substrates of at least the first and second stacks with the base substrate, at least one of the interposer substrates of the first and second stacks having an upper surface conductive contact which is electrically connected to the base substrate by a wire.

34-37. (canceled)

38. A stacked die package comprising:
a base substrate;
at least two pairs of flip chip stacks, each pair comprising a flip chip in die up orientation, a flip chip in die down orientation and an interposer substrate to which the die up and die down flip chips electrically connect;
a first of the at least two pairs of flip chip stacks adhesively bonded to the base substrate;
a second of the at least two pairs of flip chip stacks adhesively bonded to the first pair of flip chip stacks;
a first electrically conductive interconnect extending directly from and electrically interconnecting the interposer substrate of the first stack directly to the base substrate; and
a second electrically conductive interconnect extending directly from and electrically interconnecting the interposer substrate of the second stack directly to the base substrate.

39-43. (canceled)

44. A stacked die package comprising:
a base substrate;
at least two pairs of flip chip stacks, each pair comprising a flip chip in die up orientation, a flip chip in die down orientation and an interposer substrate to which the die up and die down flip chips electrically connect;
a first of the at least two pairs of flip chip stacks adhesively bonded to the base substrate;
a second of the at least two pairs of flip chip stacks adhesively bonded to the first pair of flip chip stacks;
electrically conductive interconnects electrically connecting the interposer substrates of at least the first and second stacks with the base substrate; and
an electrically insulative encapsulant received over the second stack, between the interposer substrates of the first and second stacks, and between the interposer substrate of the first stack and the base substrate.

45-46. (canceled)

47. A stacked die package comprising:
a base substrate having an upper surface and a lower surface;
at least two pairs of flip chip stacks, each pair comprising a flip chip in die up orientation, a flip chip in die down orientation and an interposer substrate to which the die up and die down flip chips electrically connect;
a first of the at least two pairs of flip chip stacks adhesively bonded to the base substrate, the die up flip chip of the first pair having a bottom surface that is adhesively bonded to the upper surface of the base substrate by at least one of a) a homogenous adhesive composition contacting the die up flip chip bottom surface of the first pair and contacting the base substrate upper surface, and b) a tape comprising an insulative substrate having an upper adhesive contacting the die up flip chip bottom surface of the first pair and a lower adhesive contacting the base substrate upper surface;
a second of the at least two pairs of flip chip stacks adhesively bonded to the first pair of flip chip stacks, the die up flip chip of the second pair having a bottom surface, the die down flip chip of the first pair having an upper surface, the die up flip chip bottom surface of the second pair being adhesively bonded to the die up flip chip upper surface of the first pair;
a first electrically conductive interconnect extending directly from and electrically interconnecting the interposer substrate of the first stack directly to the base substrate;
a second electrically conductive interconnect extending directly from and electrically interconnecting the interposer substrate of the second stack directly to the base substrate; and
an electrically insulative encapsulant received over the second stack, between the interposer substrates of the first and second stacks, and between the interposer substrate of the first stack and the base substrate.

48 and 49. (canceled)
